(19) United States
(12) Patent Application Publication
(10) Pub. No.: US 2007/0285905 A1
(43) Pub. Date: Dec. 13, 2007

(54) Electronic device, display apparatus, flexible circuit board and fabrication method thereof

(75) Inventor: Ping-Hung Wang, Tungsiao Township (TW)

Correspondence Address: LIU & LIU, 444 S. FLOWER STREET, SUITE 1750, LOS ANGELES, CA, 90071, US

(73) Assignee: Toppoly Optoelectronics Corp.

(21) Appl. No.: 11/448,551

(22) Filed: Jun. 7, 2006

(51) Int. Cl. H05K 7/00

(52) U.S. Cl. 361/760; 174/260

(57) ABSTRACT

A flexible circuit board including a base film, a first conductive layer, a second conductive layer and an adhesive layer is provided. The base film has a first surface and a second surface. The first conductive layer is disposed on the first surface of the base film directly and has a thermal bonding region. The second conductive layer is disposed above the second surface of the base film. The adhesive layer is adhered between the second conductive layer and the base film and does not overlap the thermal bonding region. Because the flexible circuit board can bear the operation temperature of the thermal bonding process, therefore, the reliability of electrical connection between flexible circuit board and PCB can be improved. Besides, only the first conductive layer is formed by sputtering, and therefore the production cost of the present invention can be reduced compared with the prior art.

### BACKGROUND OF THE INVENTION

1. Field of the Invention

The present invention generally relates to a printed circuit board and a method for fabricating the same. More particularly, the present invention relates to a flexible circuit board with higher reliability and lower production cost, and a method for fabricating the same.

2. Description of Related Art

Printed circuit boards (PCBs) are available in a variety of different types. Some PCBs are rigid, such as those having a substrate made of alumina or FR-4 glass/epoxy laminate, while others are relatively flexible (i.e., “flex circuits”), such as those having a substrate made of polyimide, polyester, and the like.

FIG. 1 is a schematic cross-sectional view showing a conventional flexible printed circuit board (FPC). Please refer to FIG. 1, the FPC 100 comprises a base film 110, a first adhesive layer 120, a second adhesive layer 130, a first conductive layer 140, a second conductive layer 150, a first cover layer 160 and a second cover layer 170. The base film 110 is conventionally composed of a flexible film such as polyimide resin, polyethylene terephthalate resin (PET) and the like, and it has a first surface 110a and a second surface 110b. The first conductive layer 140 and the second conductive layer 150 are copper foils having patterned circuits, and they are adhered to the first surface 110a and the second surface 110b of the base film 110 through the first adhesive layer 120 and the second adhesive layer 130 respectively. The first cover layer 160 and the second cover layer 170 are flexible films composed of, for example, polyimide resin, PET and the like, in order to protect the first conductive layer 140 and the second conductive layer 150.

FIG. 2 is a schematic view showing an electrical connection approach for connecting a FPC to a printed circuit board (PCB). Please refer to FIG. 2, an above-mentioned FPC 100 and a PCB 200 are provided first. The PCB 200 has a plurality of pre-solder pastes 210 on its surface, and the pre-solder pastes 210 can be lead-free solder. Next, the edge of the FPC 100 is overlapped with that of the PCB 200, and the traces 152 of the FPC 100 are placed on the corresponding pre-solder pastes 210 of the PCB 200. Then, pressure and heat are applied through a hot bar 300 to the FPC 100 so as to melt the traces 152 made of copper foil and the pre-solder pastes 210. Finally, the pressure and heat are removed so as to form solid solder joints electrically connecting the PCB 200 and the FPC 100. This is known as the “hot bar reflow” process. In order to effectively reflow the solder, the temperature of the hot bar is typically maintained at about 340˜400° C. However, the heat-resistant temperature of the adhesive layer 120 and 130 is about 60˜70° C. Therefore, the hot bar reflow process would damage the second adhesive layer 130, and the trace 152 can not be adhered to the base film 110 firmly. Thus, the reliability of the electrical connection between the FPC 100 and the PCB 200 is lower.

To overcome the problem of lower reliability due to higher operation temperature of the hot bar process, other FPC was disclosed to improve the reliability of the electrical connection between the FPC and the PCB. FIG. 3 is a schematic cross-sectional view showing other conventional FPC. Please refer to FIG. 3, the structure of the FPC 100′ is similar to that of the FPC 100 shown in FIG. 1. The difference between them is that the first conductive layer 140′ and the second conductive layer 150′ are directly disposed on the upper and the lower surface of the base film 110 respectively in the FPC 100′. The first conductive layer 140′ and the second conductive layer 150′ can be formed on the base film 110 by lamination, deposition and the like. Generally speaking, the first conductive layer 140′ and the second conductive layer 150′ are formed on the base film 110 by sputtering. Because the first conductive layer 140′ and the second conductive layer 150′ are disposed on the upper and the lower of the base film 110 directly without adhesive layers, the problem of lower reliability of electrical connection between FPC and PCB due to higher operation temperature of the hot bar process can be resolved. However, the first conductive layer 140′ and the second conductive layer 150′ are formed on one side and the other side of the base film 110 by sputtering, and therefore the production cost of the FPC 100′ would be increased.

Thus, the solution of how to provide a new FPC by taking reliability and cost into consideration is highly desired in the technology of FPC.

### SUMMARY OF THE INVENTION

Accordingly, the present invention is directed to a flexible circuit board which can bear the operation temperature of the hot bar process. Thus, the reliability of the flexible circuit board can be improved.

The present invention is also directed to a method for fabricating a flexible circuit board, in order to reduce a production cost of the flexible circuit board.

As embodied and broadly described herein, the present invention provides a flexible circuit board. The flexible circuit board mainly comprises a base film, a first conductive layer, a second conductive layer and an adhesive layer. The base film has a first surface and a second surface. The first conductive layer is disposed on the first surface of the base film directly and has a thermal bonding region. The second conductive layer is disposed above the second surface of the base film. The adhesive layer is adhered between the second conductive layer and the base film, and the adhesive layer does not overlap the thermal bonding region.

According to an embodiment of the present invention, the flexible circuit board further comprises a first passivation layer disposed on the first conductive layer. The first conductive layer does not overlap the thermal bonding region.

According to an embodiment of the present invention, the flexible circuit board further comprises a second passivation layer disposed on the second conductive layer.

As embodied and broadly described herein, the present invention also provides a display apparatus comprises a display panel, a printed circuit board and the above-mentioned flexible circuit board. The printed circuit board is disposed at one side of the display panel. The flexible circuit board is suitable for electrically connecting the display panel and the printed circuit board.

As embodied and broadly described herein, the present invention further provides an electronic device comprises the above-mentioned display apparatus and an input apparatus. The input apparatus is suitable for providing the display apparatus with information, such that an image is displayed by the display apparatus.

As embodied and broadly described herein, the present invention provides a method for fabricating a flexible circuit board. The method mainly comprises the following steps. First, a base film is provided with a first conductive layer disposed thereon, wherein the first conductive layer has a thermal bonding region. Next, a second conductive layer is provided with an adhesive layer disposed thereon. Finally, the base film and the second conductive layer are bonded together with the adhesive layer disposed therebetween, and the adhesive layer does not overlap the thermal bonding region.

According to an embodiment of the present invention, the method further comprises a step of forming a first passivation layer on the first conductive layer before bonding the base film and the second conductive layer together.

According to an embodiment of the present invention, the second conductive layer is provided on a passivation layer, and the second conductive layer is disposed between the passivation layer and the adhesive layer.

According to an embodiment of the present invention, the first conductive layer disposed on the base film is formed by deposition or lamination. More specifically, the first conductive layer disposed on the base film is formed by sputtering.

In summary, in the flexible circuit board of the present invention, there is no adhesive layer above the thermal bonding region. Therefore, when performing a thermal bonding process, such as a hot bar reflow process, no adhesive layer would be damaged due to the high operation temperature, and the reliability of electrical connection between flexible circuit board and PCB can be improved. Besides, compared with the conventional FPC, one conductive layer is formed on one side of the base film by sputtering, and the other conductive layer is adhered to the other side of the base film through an adhesive layer in the present invention. Thus, the production cost of the flexible circuit board can be reduced.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view showing a conventional flexible printed circuit board (FPC).

FIG. 2 is a schematic view showing an electrical connection approach for connecting a FPC to a printed circuit board (PCB).

FIG. 3 is a schematic cross-sectional view showing other conventional FPC.

FIG. 4 is a schematic cross-sectional view showing a flexible circuit board according to one embodiment of the present invention.

FIG. 5 is a schematic cross-sectional view showing that a flexible circuit board of the present invention is electrically connected to a PCB by using a hot bar reflow process.

FIGS. 6A to 6F are schematic, cross-sectional diagrams illustrating the process flow for fabricating a flexible circuit board according to the present invention.

FIG. 7 is a schematic diagram showing a display apparatus including the above-mentioned flexible circuit board.

FIG. 8 is a schematic block diagram showing an electronic device having the display panel as shown in FIG. 7.

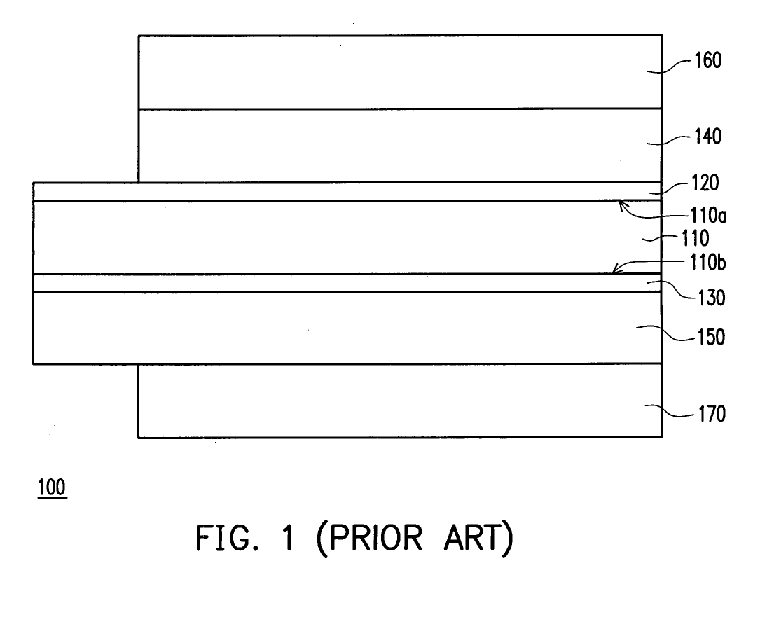

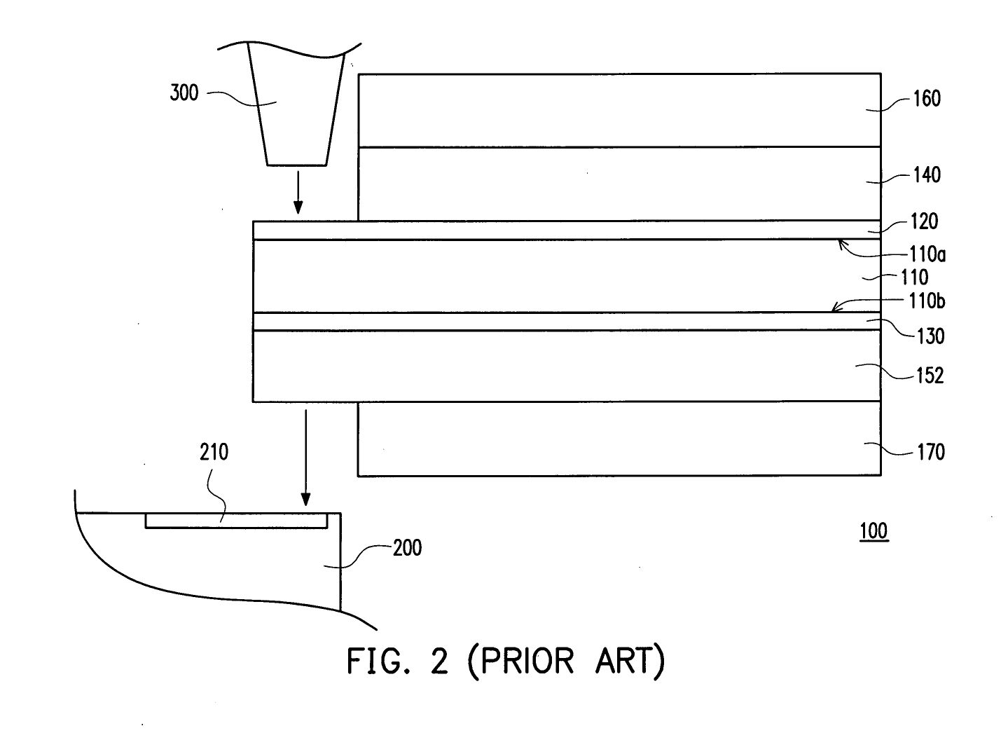

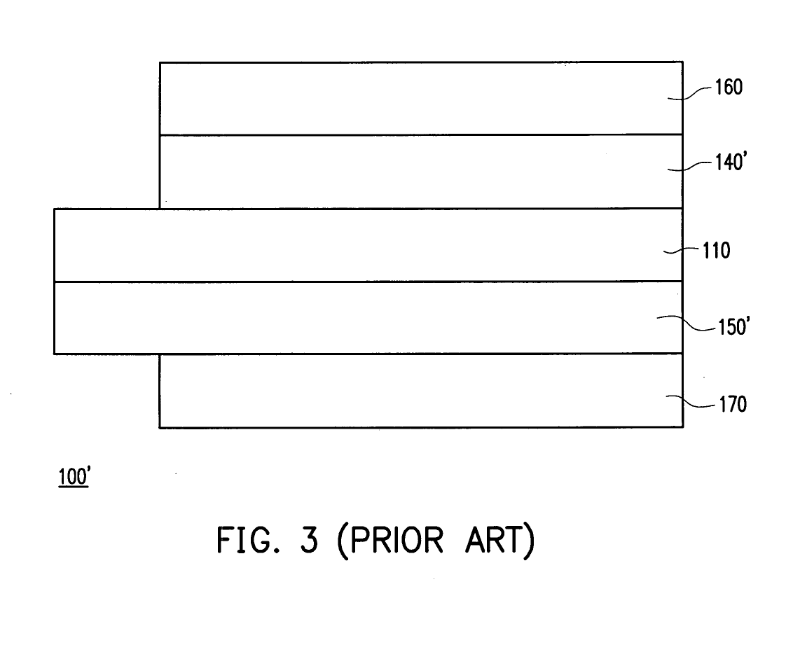

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

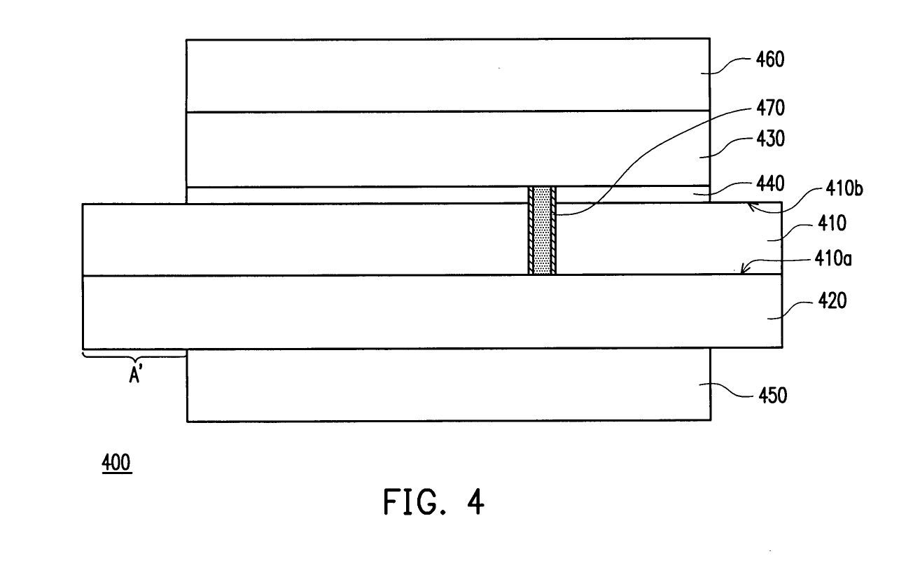

FIG. 4 is a schematic cross-sectional view showing a flexible circuit board according to one embodiment of the present invention. Please refer to FIG. 4, the flexible circuit board 400 mainly comprises a base film 410, a first conductive layer 420, a second conductive layer 430 and an adhesive layer 440. The base film 410 has a first surface 410a and a second surface 410b, and it is made of a flexible material such as polyimide, polyester, polyethylene terephthalate resin (PET) and the like. The first conductive layer 420 is disposed on the first surface 410a of the base film 410 directly and has a thermal bonding region A′ adapted for a thermal bonding process. In one embodiment of the present invention, the first conductive layer 420 can be a copper foil having a patterned circuit. The second conductive layer 430 is disposed above the second surface 410b of the base film 410, and it can also be a copper foil having a patterned circuit. The second conductive layer 430 is adhered to the base film 410 through the adhesive layer 440, and it is patterned in advance such that the adhesive layer 440 does not overlap the thermal bonding region A′.

The first passivation layer 450 is selectively disposed on the first conductive layer 420 for protecting the first conductive layer 420, and the first passivation layer 450 does not overlap the thermal bonding region A′. Similarly, the second passivation layer 460 is selectively disposed on the second conductive layer 430 for protecting the second conductive layer 430. Besides, one or more conductive plugs 470 are selectively formed in the base film 410 and the adhesive layer 440 for electrically connecting the first conductive layer 420 and the second conductive layer 430.

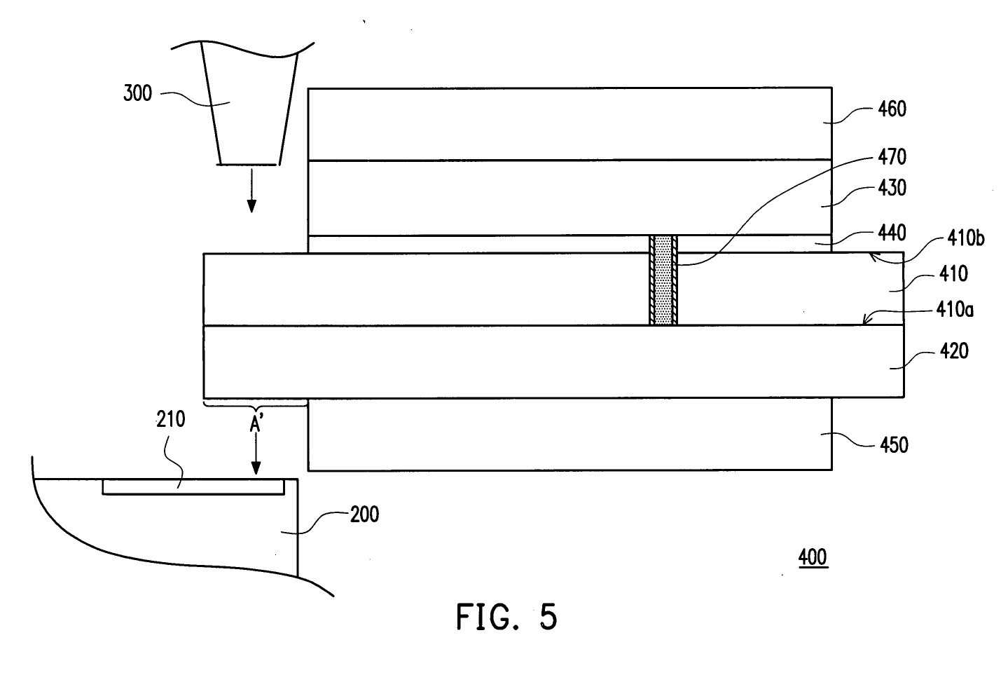

FIG. 5 is a schematic cross-sectional view showing that a flexible circuit board of the present invention is electrically connected to a PCB by using a thermal bonding process. The flexible circuit board 400 and a PCB 200 are bonded together by using a thermal bonding process, and a hot bar reflow process is taken as an example in the following for illustration. Please refer to FIG. 5, in the flexible circuit board 400 of the present invention, the adhesive layer 440 does not overlap the thermal bonding region A′. Therefore, when pressure and heat are applied through a hot bar 300 to the thermal bonding region A′ of the flexible circuit board 400 so as to melt the first conductive layer 420 and pre-solder pastes 210 of a PCB 200, no adhesive layer disposed above the thermal bonding region A′ would be damaged due to the high operation temperature. Therefore, the reliability of electrical connection between flexible circuit board 400 and the PCB 200 can be improved.

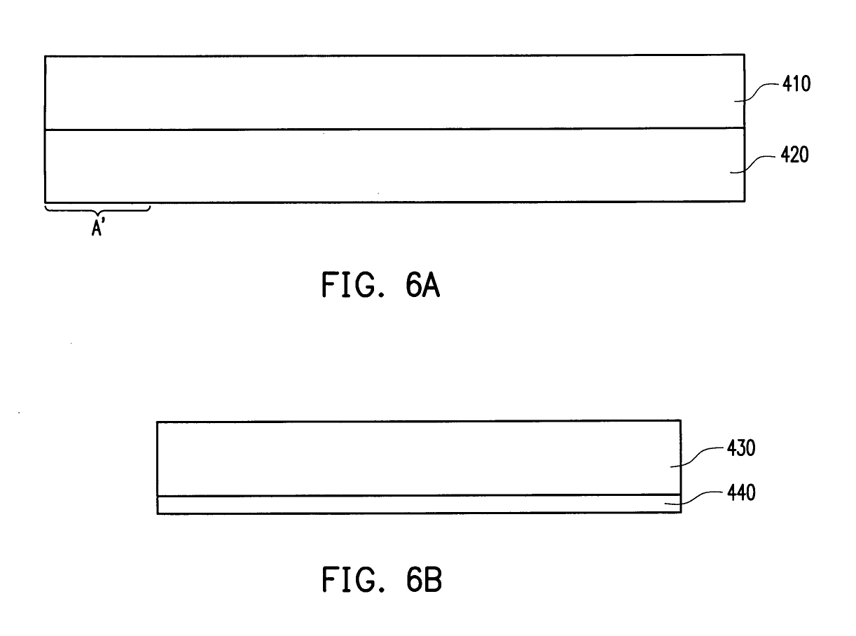

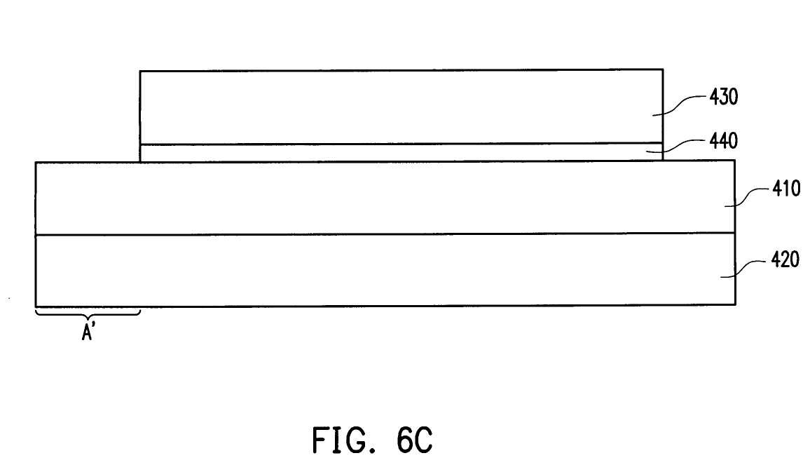

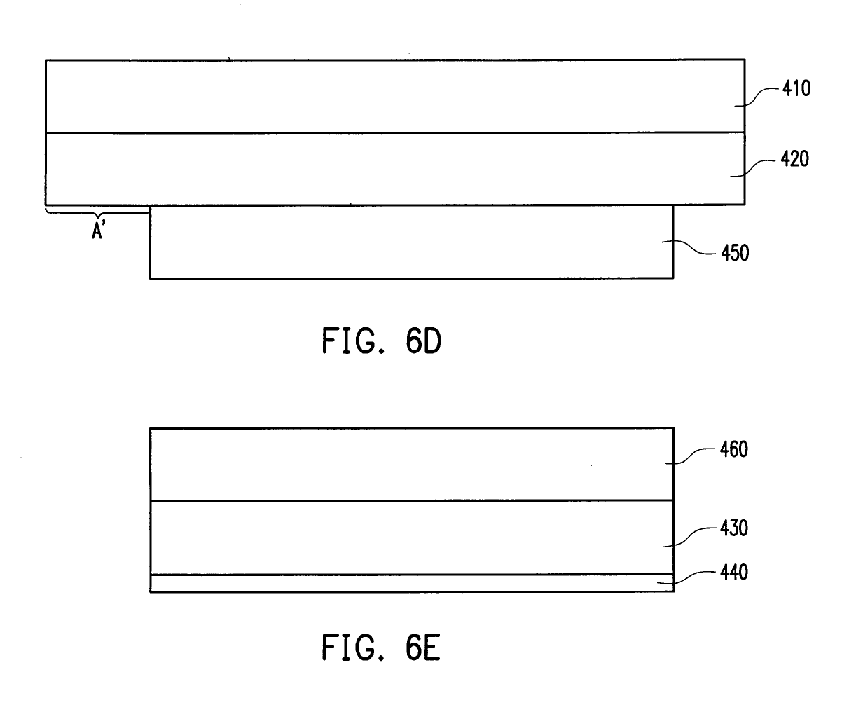

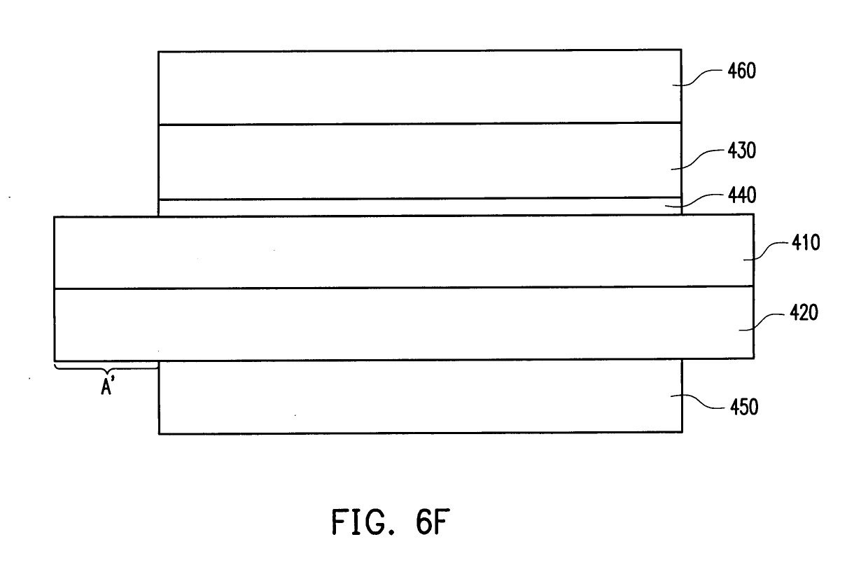

FIGS. 6A to 6F are schematic, cross-sectional diagrams illustrating the process flow for fabricating a flexible circuit board according to the present invention. First, please refer to FIG. 6A, a base film 410 is provided with a first conductive layer 420 disposed on the lower surface thereof, and the first conductive layer 420 has a thermal bonding region A′. In one embodiment of the present invention, the first conductive layer 420 disposed on the base film 410 is formed by deposition, such as sputtering, or lamination. Next, please refer to FIG. 6B, a second conductive layer 430 is provided with an adhesive layer 440 disposed thereon. Finally, please refer to FIG. 6C, the base film 410 and the second conductive layer 430 are bonded together. The adhesive layer 440 is disposed between the base film 410 and the second conductive layer 430, and the adhesive layer 440 does not overlap the thermal bonding region A′. Thus far, the basic structure of the flexible circuit board is formed according to the above processes.

Besides, please refer to FIG. 6D, before bonding the base film 410 and the second conductive layer 430 together, the method may further comprise a step of forming a first passivation layer 450 on the first conductive layer 420. The first passivation layer 450 is adapted for protecting the first conductive layer 420 and it also exposes the thermal bonding region A′. Further, please refer to FIG. 6E, the second conductive layer 430 shown in FIG. 6B can be provided on a second passivation layer 460 which is adapted for protecting the second conductive layer 430, and the second conductive layer 430 is disposed between the second passivation layer 460 and the adhesive layer 440. However, the fabrication sequence of the first passivation layer 450 and the second passivation layer 460 are not limited in the present invention.

In one embodiment of the present invention, the base film 410 shown in FIG. 6D and the second conductive layer 430 shown in FIG. 6E can be bonded together to form the flexible circuit board 400′ shown in FIG. 6F. Besides, one or more conductive plugs (not shown) can be formed in the base film 410 and the adhesive layer 440 to electrically connect the first conductive layer 420 and the second conductive layer 430 according to the requirement.

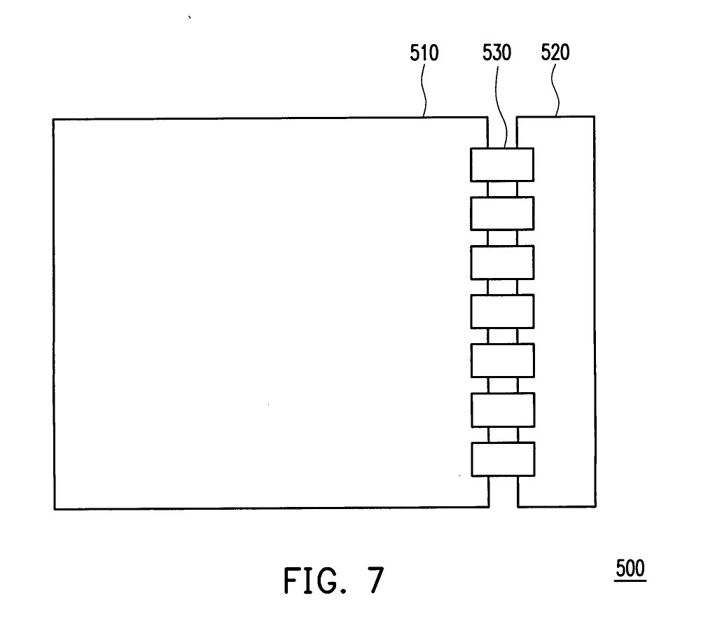

FIG. 7 is a schematic diagram showing a display apparatus including the above-mentioned flexible circuit board. Please refer to FIG. 7, the display apparatus 500 mainly comprises a display panel 510, a PCB 520 and at least one flexible circuit board 530. The display panel 510 may be an LCD display panel, a plasma display panel or an organic electroluminescence display panel, and the type of the display panel 510 is not limited in the present invention. The PCB 520 is disposed at one side of the display panel 510, and the flexible circuit board 530 is adapted for electrically connecting the display panel 510 and the PCB 520. The flexible circuit board 530 is the same as that shown in FIG. 4, so it is not repeated herein.

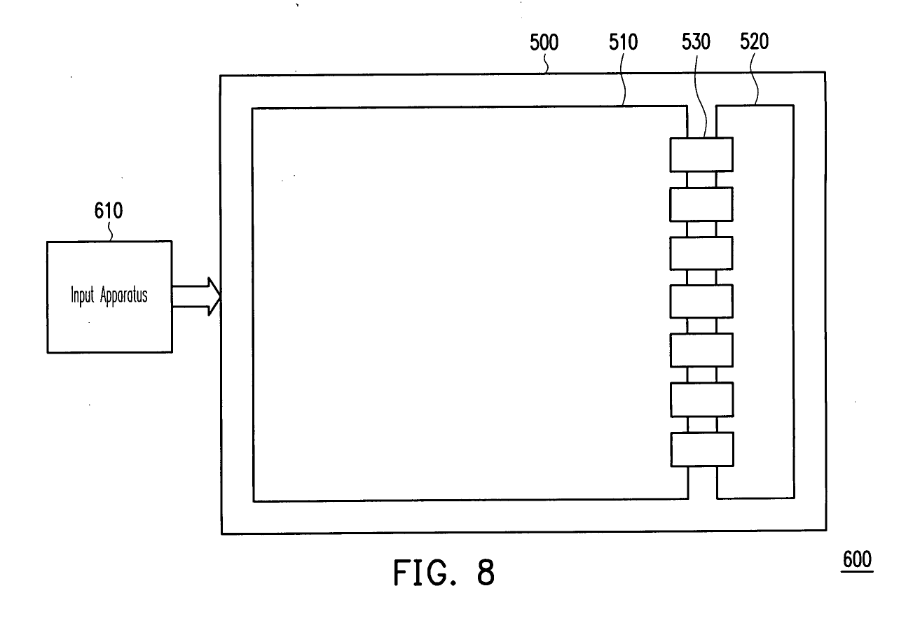

FIG. 8 is a schematic block diagram showing an electronic device having the display panel as shown in FIG. 7. Please refer to FIG. 8, the electronic device 600 of the present invention mainly comprises a display apparatus 500 as shown in FIG. 7 and an input apparatus 610 electrically connected thereto. The components of the display apparatus 500 are shown in FIG. 7, so it is not repeated herein. The input apparatus 610 is adapted for receiving commands input by users and transmitting the commands to the display apparatus 500.

In summary, the adhesive layer does not overlap the thermal bonding region in the flexible circuit board. Therefore, when performing a thermal bonding process, such as a hot bar reflow process, no adhesive layer would be damaged due to the high operation temperature, and the reliability of electrical connection between flexible circuit board and PCB can be improved. Besides, compared with the conventional FPC, one conductive layer is formed on one side of the base film by sputtering, and the other conductive layer is adhered to the other side of the base film through an adhesive layer in the present invention. Thus, the production cost of the flexible circuit board can be reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A flexible circuit board, comprising:
a base film having a first surface and a second surface;
a first conductive layer disposed on the first surface of the base film directly and having a thermal bonding region;
a second conductive layer disposed above the second surface of the base film; and
an adhesive layer adhered between the second conductive layer and the base film, wherein the adhesive layer does not overlap the thermal bonding region.

2. The flexible circuit board according to claim 1, further comprising a first passivation layer disposed on the first conductive layer, wherein the first passivation layer does not overlap the thermal bonding region.

3. The flexible circuit board according to claim 1, further comprising a second passivation layer disposed on the second conductive layer.

4. The flexible circuit board according to claim 1, further comprising at least one conductive plug formed in the base film and the adhesive layer for electrically connecting the first conductive layer and the second conductive layer.

5. The flexible circuit board according to claim 1, wherein the material of the base film comprises polyimide, polyester or polyethylene terephthalate resin (PET).

6. The flexible circuit board according to claim 1, wherein the first conductive layer is a copper foil.

7. The flexible circuit board according to claim 1, wherein the second conductive layer is a copper foil.

8. A display apparatus, comprising:
a display panel;
a printed circuit board, disposed at one side of the display panel; and
at least one flexible circuit board as recited in claim 1, for electrically connecting the display panel and the printed circuit board.

9. An electronic device, comprising:
a display apparatus, as recited in claim 8; and
an input apparatus, suitable for providing the display apparatus with information, such that an image is displayed by the display apparatus.

10. A method for fabricating a flexible circuit board, comprising the following steps:
providing a base film with a first conductive layer disposed thereon, wherein the first conductive layer has a thermal bonding region;
providing a second conductive layer with an adhesive layer disposed thereon; and
bonding the base film and the second conductive layer together with the adhesive layer disposed therebetween, wherein the adhesive layer does not overlap the thermal bonding region.

11. The method for fabricating a flexible circuit board according to claim 10, further comprising a step of forming a conductive plug in the base film for electrically connecting the first conductive layer and the second conductive layer.

12. The method for fabricating a flexible circuit board according to claim 10, further comprising a step of forming a first passivation layer on the first conductive layer before bonding the base film and the second conductive layer together.

13. The method for fabricating a flexible circuit board according to claim 10, wherein the second conductive layer is provided on a passivation layer, and the second conductive layer is disposed between the passivation layer and the adhesive layer.

14. The method for fabricating a flexible circuit board according to claim 10, wherein the first conductive layer disposed on the base film is formed by deposition or lamination.

15. The method for fabricating a flexible circuit board according to claim 14, wherein the first conductive layer disposed on the base film is formed by sputtering.
